(19) United States
(12) Patent Application Publication
(10) Pub. No.: US 2026/0255905 A1
(43) Pub. Date: Aug. 27, 2026

(54) SUBSTRATE TREATMENT DEVICE AND GAS SUPPLY METHOD

(71) Applicant: WONIK IPS Co., Ltd, Pyeongtaek-si, Gyeonggi-do (KR)

(72) Inventors: Dae Seong LEE, Pyeongtaek-si, Gyeonggi-do (KR); Won Jun JANG, Pyeongtaek-si, Gyeonggi-do (KR); Joo Suop KIM, Pyeongtaek-si, Gyeonggi-do (KR); Kyung PARK, Pyeongtaek-si, Gyeonggi-do (KR); Jin Seo KIM, Pyeongtaek-si, Gyeonggi-do (KR); Sang Rok NAM, Pyeongtaek-si, Gyeonggi-do (KR); Chang Hun KIM, Pyeongtaek-si, Gyeonggi-do (KR); Su Hwan KIM, Pyeongtaek-si, Gyeonggi-do (KR); Seong Hee LEE, Pyeongtaek-si, Gyeonggi-do (KR); Tae Kyun KIM, Pyeongtaek-si, Gyeonggi-do (KR)

(21) Appl. No.: 18/874,934

(22) PCT Filed: Nov. 9, 2022
(86) PCT No.: PCT/KR2022/017577

§ 371 Date: Dec. 13, 2024

(30) Foreign Application Priority Data
Aug. 25, 2022 (KR) 10-2022-0106551

(51) Int. Cl. H10P 72/00

(52) U.S. Cl. CPC H10P 72/0402; H10P 72/0604

(57) ABSTRACT

A substrate processing equipment includes a process chamber (100) forming a processing space in which substrate processing is performed, a plurality of gas supplying units (200), and a control unit (300) for controlling supply of different process gases through the gas supplying units (200) based on the sensing result of the gas sensing means. Each of the plurality of gas supplying units comprises a supply line (210) formed with a supply flow path communicating with the processing space and delivering process gas from a process gas supply source (270), a supply valve (220) installed in the supply line (210) to open and close the supply flow path, and gas sensing means for sensing the process gas at a rear end of the supply valve (220) in the supply line (210).

### TECHNICAL FIELD

The present invention relates to a substrate processing equipment and a gas supply method, and more specifically to a substrate processing equipment and gas supply method for supplying different gases in a substrate processing equipment.

### BACKGROUND ART

In general, a substrate processing equipment is an apparatus that performs processes such as deposition, etching, and heat treatment on a substrate. By positioning the substrate within the substrate processing equipment and supplying process gases and creating an appropriate temperature environment, substrate processing can be carried out.

Typically, substrate processing equipment uses different process gases, and depending on the type of process being performed, these different process gases can be supplied simultaneously or separately with a time delay.

Particularly, in cases where different process gases mix during the supply process and react, this can result in unintended reactions within the process chamber or cause problems such as explosions or the generation of harmful substances.

To improve such problems, conventional substrate processing equipment applied a structure using mutual interlocking on separate supply lines for each process gas, preventing the phenomenon of other process gases being supplied when one process gas is being supplied.

However, in the case of conventional substrate processing equipment, while preventing the simultaneous supply of different process gases through interlocking between valves on the supply lines, there was a difficulty in detecting gas leakage or intrusion, particularly at the valves on the supply lines.

Particularly, when process gases leak or intrude in the supply lines, there exists a possibility that different process gases can mix, which consequently leads to equipment safety issues such as explosions or the generation of harmful substances.

More specifically, conventional substrate processing equipment supplied and blocked process gases through valves while the supply lines were filled with process gases. In this case, the supply lines maintain a state of being filled with process gases, and the positive pressure is continuously maintained through pressure measurement. Consequently, this creates difficulty in detecting and responding to leakage or intrusion of process gases within the supply lines.

Furthermore, when process gases leak or intrude into the supply lines, different process gases can mix together in the supply lines, resulting in a deterioration of process quality.

### DISCLOSURE OF THE INVENTION

### Technical Problem

The object of the present invention is to provide a substrate processing equipment and a gas supply method that can prevent the mixing of different process gases, thereby solving the above-mentioned problems.

### Technical Solution

In accordance with an embodiment of the present invention, there is provided with a substrate processing equipment which includes a process chamber (100) forming a processing space in which substrate processing is performed; a plurality of gas supplying units (200), respectively comprising a supply line (210) formed with a supply flow path communicating with the processing space and delivering process gas from a process gas supply source (270), a supply valve (220) installed in the supply line (210) to open and close the supply flow path, and gas sensing means for sensing the process gas at a rear end of the supply valve (220) in the supply line (210); a control unit (300) for controlling supply of different process gases through the gas supplying units (200) based on the sensing result of the gas sensing means, wherein prior to supplying process gas through at least one of the plurality of gas supplying units (200), the control unit (300) checks whether to block based on the sensing result of the gas sensing means of at least one of the remaining gas supplying units (200).

The gas sensing means may be a pressure sensor (230) that measures pressure of the supply flow path at the rear end of the supply valve (220), and the control unit (300) may check whether to block supply of process gases before supplying process gases through any one of the gas supply units (200), based on pressure measurement value from the pressure sensor (230) of at least one of the remaining gas supply units (200).

The control unit (300) may start to supply process gases through any one of the gas supply units (200), by comparing pressure measurement value from the pressure sensor (230) of at least one of the gas supply units (200) except at least one of the gas supply units (200) where process gas supply is scheduled, with a preset reference value, and when the measured pressure is lower than or equal to the reference value

The control unit (300) may start to supply process gases through any one of the gas supply units (200) which is scheduled for process gas supply, when the pressure measurement value of the pressure sensor (230) of at least one of the gas supply units (200) is lower than or equal to a predetermined threshold value.

The control unit (300) may start to supply process gases through any one of the gas supply units (200), when the pressure measurement value from the pressure sensor (230) of at least one of the gas supply units (200) except any one of the gas supply units (200) where process gas supply is scheduled, is negative pressure.

The control unit (300) may block the supply valve (220) corresponding to the pressure sensor (230) that measures pressure exceeding preset reference value by comparing the pressure measurement value from the pressure sensor (230) of at least one of the remaining gas supply units (200) except the any one of the gas supply units (200), with the preset reference value, and when the pressure measurement value exceeds the reference value.

The control unit (300) may block supply of process gases from the above process gas supply source (270) by comparing the pressure measurement value from the pressure sensor (230) of at least one of the remaining gas supply units (200) except any one of the gas supply units (200), with the preset reference value, and when the pressure measurement value exceeds the reference value.

The control unit (300) may check whether the process gas is being supplied normally by using the pressure measurement value from the pressure sensor (230) of at least one gas supply unit (200), during the supply of process gas through any one of the gas supply units (200).

A main supply line (600) the end of which is connected with the process chamber (100), and which is connected with the respective supply lines (210) of the plurality of gas supplying units (200), may be further provided with.

The plurality of gas supplying units (200) may comprise a first gas supply unit (400) comprising a first gas supply unit (400) comprising a first supply line (410) formed with a supply flow path for supplying first process gas, the supply flow path communicating with the processing space, a first supply valve (420) installed in the first supply line (410) to open and close the supply flow path, and a first pressure sensor (430) installed at the rear end of the first supply valve (420) in the first supply line (410) to measure the pressure of the supply flow path, and a second gas supply unit (500) comprising a second supply line (510) formed with a supply flow path for supplying second process gas, the supply flow path communicating with the processing space, a second supply valve (520) installed in the second supply line (510) to open and close the supply flow path, and a second pressure sensor (530) installed at the rear end of the second supply valve (520) in the second supply line (510) to measure the pressure of the supply flow path.

The first gas supply unit (400) may further comprise a first control valve (440) which is installed at the rear end of the first supply valve (420) in the first supply line (410) to control flow rate of the first process gas, and the first pressure sensor (430) may be installed at at least one of the front end and the rear end of the first control valve (440).

The second gas supply unit (500) may further comprise a second control valve (540) which is installed at the rear end of the second supply valve (520) in the second supply line (510) to control flow rate of the second process gas, and the second pressure sensor (530) may be installed at at least one of the front end and the rear end of the second control valve (540).

In accordance with an embodiment of the present invention, there is also provided with a gas supply method trough a substrate processing equipment comprising a process chamber (100) forming a processing space in which substrate processing is performed; a plurality of gas supplying units, respectively comprising a supply line formed with a supply flow path communicating with the processing space, a supply valve installed in the supply line to open and close the supply flow path and a pressure sensor for measuring pressure in the supply flow path at a rear end of the supply valve in the supply line, comprising first process gas supplying step (S100) for supplying a first process gas to the processing space through a first gas supply unit (400) of the plurality of gas supplying units; first pressure checking step (S300) for checking whether the measured value of the first pressure sensor (430) of the first gas supply unit (400) is lower than or equal to preset reference value after the first process gas supplying step (S100); and second process gas supplying step (S400) for supplying second process gas different from the first process gas through a second gas supply unit (500) of the plurality of gas supplying units when the measured value is lower than or equal to the reference value.

First process gas cleaning step (S200) for performing cleaning of the first gas supply unit (400) after the first process gas supplying step (S100) may be further provided with.

The first process gas cleaning step (S200) may comprise supply line purging step (S210) for purging a first supply line (410) of the first gas supply unit (400), and supply line pumping step (S220) for performing pumping the first supply line (410) after the supply line purging step (S210).

The first pressure checking step (S300) may comprise first pressure measurement step (S310) for measuring pressure of the supply flow path through the first pressure sensor (430), and first pressure comparison step (S320) for comparing the measured value from the first pressure measurement step (S310) with the preset reference value.

Supply valve blocking step (S500) for blocking the first supply valve (420) of the first gas supply unit (400), when measured value through the first pressure checking step (S300) exceeds the preset reference value, may be provided with.

The respective supply valves of the plurality of gas supply units may be blocked in the supply valve blocking step (S500).

The first pressure checking step (S300) may further comprise step for checking whether measured value from the second pressure sensor (530) of the second gas supply unit (500) is below or equal to the preset reference value.

Second pressure checking step (S600) for checking whether measured value from the second pressure sensor (530) of the second gas supply unit (500) is below or equal to the preset reference value after the second gas supply step (S400) may be further provided with, and the first gas supply step (S100), the first pressure checking step (S300), the second gas supply step (S400) and the second pressure checking step (S600) may be sequentially performed to form one single cycle and at least one of the single cycles may be performed.

### Advantageous Effects

The substrate processing equipment and the gas supply method in accordance with the present invention has an advantage of being able to prevent and respond to the phenomenon of being mixed with different process gases and supplied by monitoring the state of each supply line for different process gases.

In addition, the substrate processing equipment and the gas supply method in accordance with the present invention has an advantage in that through monitoring of each process gas, it is possible to detect process gas leakage and intrusion in the supply line, and by responding to this, mixed process gases can be blocked from mixing, thereby preventing equipment safety issues such as explosions and the generation of hazardous substances.

In addition, the substrate processing equipment and the gas supply method in accordance with the present invention has an advantage in that through monitoring of process gas leaks, it is possible to pre-identify and confirm leaks and intrusion in the supply line and the valve beforehand, which can shorten maintenance time.

### BRIEF DESCRIPTION OF THE DRAWINGS

FIG. 1 is a simplified diagram showing the substrate processing equipment according to the present invention.

FIG. 2 is a partial view showing a part of a gas supply unit in the substrate processing equipment of FIG. 1.

FIG. 3 is a flowchart showing the gas supply method according to the invention.

FIG. 4 is a flowchart showing the case where the measured pressure value exceeds the reference value in accordance with the first pressure checking step.

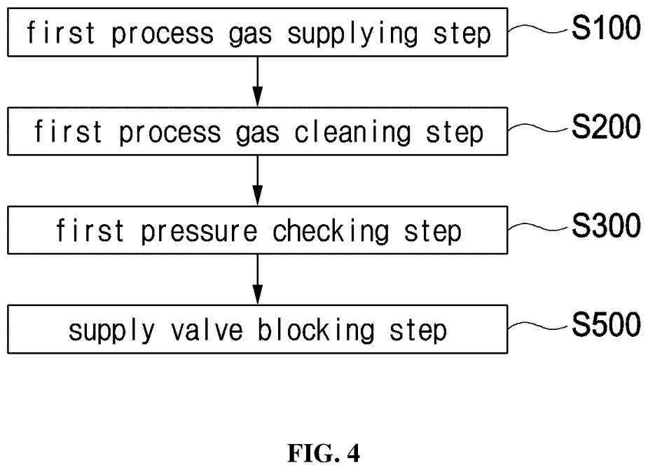

### MODE FOR CARRYING OUT THE INVENTION

Hereinafter, the substrate processing equipment in accordance with the present invention will be described with reference to the accompanying drawings.

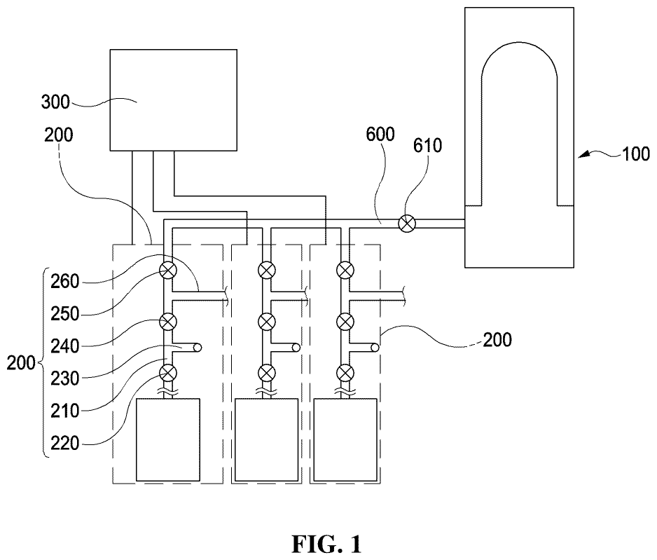

As shown in FIG. 1, the substrate processing equipment in accordance with the present invention includes a process chamber (100) forming a processing space in which substrate processing is performed; a plurality of gas supplying units (200), respectively comprising a supply line (210) formed with a supply flow path communicating with the processing space and delivering process gas from a process gas supply source (270), a supply valve (220) installed in the supply line (210) to open and close the supply flow path, and gas sensing means for sensing the process gas at a rear end of the supply valve (220) in the supply line (210); and a control unit (300) for controlling supply of different process gases through the gas supplying units (200) based on the sensing result of the gas sensing means

In addition, the substrate processing equipment in accordance with the present invention may further include a main supply line (600) the end of which is connected with the process chamber (100), and which is connected with the respective supply lines (210) of the plurality of gas supplying units (200).

Here the substrate to be processed may include substrates for semiconductor device, light emitting diode (LED) and liquid crystal display (LCD) display, solar cell substrate, glass substrate, etc., as well as any other type of substrate that has been previously disclosed in the prior art.

Substrate processing refers to a process that includes deposition, etching, heat treatment, and other processes, and may particularly refer to an annealing process to improve thin film quality.

Therefore, the substrate processing may be performed at a high temperature environment of 600° C. or higher, and in the high temperature environment, there is a risk of explosion and generation of hazardous substances if mixing occurs in types of supplied process gases.

In the present invention, the process gas refers to the gas used for substrate processing, and plurality of types of gases can be used.

For example, in the present invention, ammonia (NH3), hydrogen (H2), and oxygen (O2) are examples of gases that can be used as process gas. Particularly, hydrogen (H2) as the first process gas, and oxygen (O2) as the second process gas, are alternatively supplied to the processing chamber (100) inside the processing space to perform substrate processing.

When hydrogen (H2) and oxygen (O2) are supplied alternately, there is a risk of explosion if they mix with each other, which can cause an equipment safety issue.

Therefore, it is necessary to monitor, prevent and response to leaks of each process gas within the supply lines, so that different types of first process gas and second process gas supplied alternately for substrate processing do not mix with each other.

The process chamber (100) in accordance with the present invention may have various configurations that form a processing space for substrate processing.

For example, the process chamber (100) may be a single-substrate type equipment where one substrate is introduced and processed, or a batch-type equipment where plural substrates are introduced through a substrate mounting unit and processed simultaneously.

For example, if the process chamber (100) is a batch-type equipment, the process chamber (100) may have an internal processing space formed by a process tube that accommodates a substrate mounting unit stacked with plural substrates and is connected to the main supply line (600) which will be described hereinafter, and may be provided with a manifold through which plurality of different types of process gases, including the first process gas and the second process gas are supplied.

As a result, the process chamber (100) may perform substrate processing by being loaded with the substrate mounting unit stacked with plural substrates.

Meanwhile, the process chamber (100) may be composed of various materials. For example, the process chamber (100) may be made of quartz, stainless steel (SUS), aluminum, graphite, silicon carbide, or aluminum oxide.

The gas supplying unit (200) may include a supply line (210) formed with a supply flow path communicating with the processing space, a supply valve (220) installed in the supply line (210) to open and close the supply flow path, and gas sensing means for sensing the process gas at a rear end of the supply valve (220) in the supply line (210).

In addition, the gas supply unit (200) may further include a front end control valve (240) and a rear end control valve (250) located after the pressure sensor (230) in the supply line (210).

In addition, the gas supply unit (200) may further include a purge gas supply line (260) that connects to the supply line (210) and supplies purge gas to the supply flow path.

In the following description, the rear end refers to the side of the supply line (210) towards the process chamber (100), and the front end refers to the opposite side, i.e., the direction towards the process gas supply source (270).

The supply line (210) may be a structure that forms a supply flow path communicating with the processing space, and the supply line (210) may have various configurations.

For example, the supply line (210) may be connected to the process gas supply source (270) at one end and to the main supply line (600) at the other end. This way, process gases supplied from the process gas supply source (270) may be delivered through the main supply line (600) to the processing space.

Meanwhile, the supply line (210) may be connected directly to the process chamber (100), omitting the main supply line (600), and delivering process gases directly from the gas source (270) to the processing space.

The supply line (210) may be a pipe that forms an internal supply flow path, and through the supply valve (220) which will be described hereinafter, the front end control valve (240), and the rear end control valve (250), it may be determined whether to supply process gases and at what flow rate.

In addition, the supply line (210) may be combined with the purge gas supply line (260) to perform purging inside the supply flow path, and cleaning and pumping may be performed after supplying process gases.

The supply valve (220) may be installed in the supply line (210), forming a structure that opens or closes the supply flow path, and the supply valve (220) may have various configurations.

For example, the supply valve (220) may be installed at the side connected to the process gas supply source (270) in the supply line (210), allowing it to open or close the supply flow path. This enables the supply or the blocking of process gases through the supply line (210).

Meanwhile, to the front end of the supply valve (220) in the supply line (210) may be maintained in a state where supplied process gases are filled with. When the supply valve (220) is blocked, an empty state in the supply flow path may be formed at the rear end of the supply valve (220), and thus the pressure in the supply flow path at the rear end of the supply valve (220) before supplying process gas may be negative pressure state.

The gas detection means may be located at the rear end of the supply valve (220) in the supply line (210) and form a structure that detects the existence of process gas inside the supply flow path and may have various configurations.

For example, the gas detection means may use a flow sensor to measure the presence and flow rate of process gas in the supply flow path, a gas detection sensor to detect the presence of process gas, and a pressure sensor (230) to measure the internal pressure of the supply flow path and determine the presence and flow rate of process gas. In addition, any other means that can be applied to judge the presence or absence of process gas in the supply flow path inside the supply line (210) can also be utilized.

Hereinafter an example where a pressure sensor (230) is applied as the gas detection means is described, but the other same elements may be applied to the same.

The pressure sensor (230) may be located at the rear end of the supply valve (220) in the supply line (210) and measure the pressure in the supply line and may have various configurations.

As previously described, the pressure sensor (230) located at the rear end of the supply valve (220) may create the relatively lower pressure than the outside pressure, for example negative pressure state before process gas is supplied, and the relatively higher pressure than the outside pressure for example positive pressure state after process gas is supplied.

In this way, the pressure sensor (230) may measure the pressure of the supply flow path and confirm whether process gas is being supplied normally and whether there is a leak of process gas at a specific location within the supply flow path.

The front end control valve (240) may be an additional configuration that can be provided at the rear end of the pressure sensor (230) in the supply line (210), and it may be a configuration for adjusting the flow rate of process gas to be supplied.

At this time, the front end control valve (240) may control the flow rate of process gas being supplied by adjusting the opening ratio of the supply flow path in the supply line (210), and it can also be fully opened or fully closed as needed.

The rear end control valve (250) may be an additional configuration that can be provided at the rear end of the front end control valve (240) in the supply line (210), and it may be a configuration for adjusting the flow rate of process gas to be supplied.

At this time, the rear end control valve (250) may control the flow rate of process gas being supplied by adjusting the opening ratio of the supply flow path in the supply line (210), and it can also be fully opened or fully closed as needed. Additionally, it can adjust the flow rate of process gas being supplied to an appropriate level by being combined with the front end control valve (240) mentioned above.

Meanwhile, the pressure sensor (230) may be installed in at least one of the locations of between the front end control valve (240) and the supply valve (220), between the front end control valve (240) and the rear end control valve (250), and at the rear end of the rear end control valve (250).

The purge gas supply line (260) may be connected to the supply line (210) and supplies purge gas to the supply flow path, and various configurations are possible.

Particularly, the purge gas supply line (260) may perform a purge in the supply flow path within the supply line (210) by supplying inert gas to the supply line (210), for example, after process gas supply through the supply line (210) has been completed, inert gas can be supplied into the supply line (210) to purge any remaining process gas.

Meanwhile, the gas supply unit (200) may be configured to be comprised of in plural corresponding to the different types of process gases that are being supplied.

At this time, the gas supply unit (200) may supply process gases in time delay to prevent the mixing of process gases being supplied. Each of the gas supply units (200) may have the same configuration as mentioned above, except the type of process gas being supplied.

For example, the gas supply unit (200) may include a first process gas supply unit (400) for supplying the first process gas and a second process gas supply unit (500) for supplying the second process gas. The first process gas supply unit (400) and the second process gas supply unit (500) alone may be configured as mentioned, or additional gas supply units (200) may be added.

The first process gas supply unit (400) may include a first supply line (410) formed with a supply flow path for supplying first process gas, the supply flow path communicating with the processing space, a first supply valve (420) installed in the first supply line (410) to open and close the supply flow path, and a first pressure sensor (430) installed at the rear end of the first supply valve (420) in the first supply line (410) to measure the pressure of the supply flow path.

In addition, the first gas supply unit (400) may further include a first control valve (440) which is installed at the rear end of the first supply valve (420) in the first supply line (410) to control flow rate of the first process gas.

In addition, the first process gas supply unit (400) may include a first rear end control valve (450) installed at the rear end of the first control valve (440) in the first supply line (410), which controls the flow rate of the first process gas.

In addition, the first process gas supply unit (400) may include a first purge gas supply line (460) connected to the first supply line (410), which supplies purge gas to the supply flow path.

In addition, the first process gas supply unit (400) may also include a first process gas supply source (270) connected to the first supply line (410), which supplies the first process gas.

The second gas supply unit (500) may include a second supply line (510) formed with a supply flow path for supplying second process gas, the supply flow path communicating with the processing space, a second supply valve (520) installed in the second supply line (510) to open and close the supply flow path, and a second pressure sensor (530) installed at the rear end of the second supply valve (520) in the second supply line (510) to measure the pressure of the supply flow path.

Here the second gas supply unit (500) further comprises a second control valve (540) which is installed at the rear end of the second supply valve (520) in the second supply line (510) to control flow rate of the second process gas.

In addition, the second gas supply unit (500) may further include a second rear end control valve (550) installed at the rear end of the second control valve (540) in the second supply line (510), which controls the flow rate of the second process gas.

In addition, the second process gas supply unit (500) may further include a second purge gas supply line (560) connected to the second supply line (510), which supplies purge gas to the supply flow path.

In addition, the second process gas supply unit (500) may also include a second process gas source (570) connected to the second supply line (510), which supplies the second process gas.

At this time, the first and the second process gases are gases that can cause explosive safety issues if mixed together. For example, the first process gas may be hydrogen gas, while the second process gas may be oxygen gas as previously described.

The first supply line (410) and the second supply line (510), the first supply valve (420) and the second supply valve (520), the first pressure sensor (430) and the second pressure sensor (530), the first control valve (440) and the second control valve (540), the first rear end control valve (450) and the second rear end control valve (550), and the first purge gas supply line (460) and the second purge gas supply line (560) may have the same configuration as previously described, with identical element. Further description of those is omitted.

The first process gas source (470) and the second process gas source (570) may be configured to store and supply the first process gas and the second process gas, respectively.

At this time, the first pressure sensor (430) may be installed on either or both of the front end and the rear end of the first control valve (440), and the second pressure sensor (530) may be installed on either or both of the front end and the rear end of the second control valve (540).

The control unit (300) may control the supply of different process gases through each gas supply unit (200), based on pressures measured by the respective pressure sensors (230) of the gas supply units (200).

Particularly, the control unit (300) may check whether to block the supply of process gases through at least one of the plurality of gas supply units (200) before supplying process gas therethrough, based on pressure measurement value from the pressure sensor (230) of the remaining gas supplying units (200).

In other words, the control unit (300) may ensure that process gases supplied in sequence in time delay do not mix together by checking whether to block the supply of different process gases from other gas supply units (200) before supplying a specific process gas.

In addition, the control unit (300) may ensure and prevent mixing between different process gases by checking for leaks or intrusion of process gases into the supply lines (210) inside a specific gas supply unit (200), based on pressure measurement value from the pressure sensor (230).

In more detail, the control unit (300) may start to supply process gases through any one of the gas supply units (200), by comparing pressure measurement value from the pressure sensor (230) of at least one of the gas supply units (200) except any one of the gas supply units (200) where process gas supply is scheduled, with a preset reference value, and when the measured pressure is lower than or equal to the reference value

In other words, when the pressure measurement at the rear end of the control valve (220) shows a value below a preset reference value at the state that the respective control valves of the plurality of the gas supply units (200) are blocked, it is assumed that there are no leaks in the process gas supply line (210), and thus the supply of a new process gas may start.

In this case, the preset reference value may be either 0 or an external pressure value of the supply line (210). The control unit (300) may start to supply process gases through any one of the gas supply units (200), when the pressure measurement value of the pressure sensor (230) of at least one of the gas supply units (200) except any one of the gas supply units (200) where process gas supply is scheduled, is negative pressure.

In other words, when the control valve (220) is blocked and there is no residual process gas in the supply flow path in the supply line (210), the pressure at the rear end of the control valve (220) is maintained at negative pressure state. If leakage occurs at the rear end of the control valve (220), the pressure will change to a positive pressure state. In this case, the control unit (300) may detect the leakage by measuring the pressure with the pressure sensor (230).

Therefore, the control unit (300) may start a new process gas supply when at least one of the pressure measurement values measured by the pressure sensors (230) at least one of the plurality of gas supply units (200) is below the reference value.

Through this function, the control unit (300) may prevent mixing through the pressure measurement value for the gas supply unit (200) supplying the specific process gas of the gas supply units (200) and the other gas supply unit (200) supplying the other process gas which must not be mixed with the specific gas, thereby increasing safety.

Meanwhile, to further increase safety, the control unit (300) may also determine that all measurement values from the pressure sensors (230) of the remaining gas supply units (200), except the gas supply units (200) which is scheduled to supply a specific type process gas, are below the reference value.

In addition, the control unit (300) may compare the pressure measurement value obtained from the pressure sensor (230) of the gas supply unit (200) supplying the specific process gas with the preset reference value, determine whether the pressure measurement value is below the reference value, and start to the supply of the process gas through the gas supply unit (200) where process gas supply is scheduled when below the reference value.

Meanwhile, the control unit (300) may compare the pressure measurement value obtained from the pressure sensors (230) at least one of the remaining gas supply units (200) except one of the gas supply units (200) with a preset reference value and the control unit (300) may block the control valve (220) corresponding to the pressure sensor (230) when the pressure measurement value exceeds the reference value.

In other words, the control unit (300) may start the supply of process gas when the pressure measurement value is below the reference value, and on the other hand, if the pressure measurement value exceeds the reference value, the control unit (300) may determine that there has been a leak of process gas in the supply line (210) and may block the control valve (220) corresponding to the pressure sensor (230) that exceeded the reference value.

In addition, the control unit (300) may also block all control valves (220) of the plurality of gas supply units (200) or generate alarm.

In addition, the control unit (300) may block the supply of process gas from the process gas supply source (270) by controlling the process gas supply source (270) because leaks due to damage of the function of the control valve (220) may occur at the rear end of the control valve (220).

In other words, the control unit (300) may fundamentally block the supply of process gas from the process gas supply source (270) when the pressure measurement value from the pressure sensor (230) of at least one of the remaining gas supply units (200) except one of the gas supply units (200) is compared with the preset reference value, and exceeds the reference value.

In addition, the control unit (300) may check whether the process gas is being supplied normally by not only the pressure measurements of the plurality of gas supply units (200) before starting the supply of process gas, but also the pressure measurement value obtained from the pressure sensor (230) of the gas supply unit (200) supplying the process gas during the supply of process gas through one of the gas supply units (200).

In other words, the control unit (300) may check whether the pressure measurement value obtained from the pressure sensor (230) of the gas supply unit (200) supplying process gas falls within a reference range of the positive pressure. If the pressure measurement value does fall within the reference range, the control unit (300) may determine that the process gas is being supplied normally. If there is negative pressure state, the control unit (300) may determine that no process gas is being supplied. And if the pressure measurement value is out of the reference range of positive pressure, the control unit (300) may determine that the process gas supply is abnormal.

Meanwhile, the control unit (300) may, in the event that the control unit (300) determines that the process gas supply is not normal, generate alarm as previously described, block the control valve (220), and if necessary, fundamentally block the supply of process gas from the process gas supply source (270).

The main supply line (600) may combine the respective supply lines (210) of the plurality of the gas supply units (200) which are connected to the process chamber (100) at its end, allowing for the supply of process gas from the supply line (210) into a processing space within the process chamber (100).

The main supply line (600) is equipped with a separate valve (610), allowing for final control of the supply of process gas into the processing space, together with not only whether to supply or not, but also flow rate.

In addition, the main supply line (600) may be omitted, and the plurality of the supply lines (210) may be connected directly to the process chamber (100).

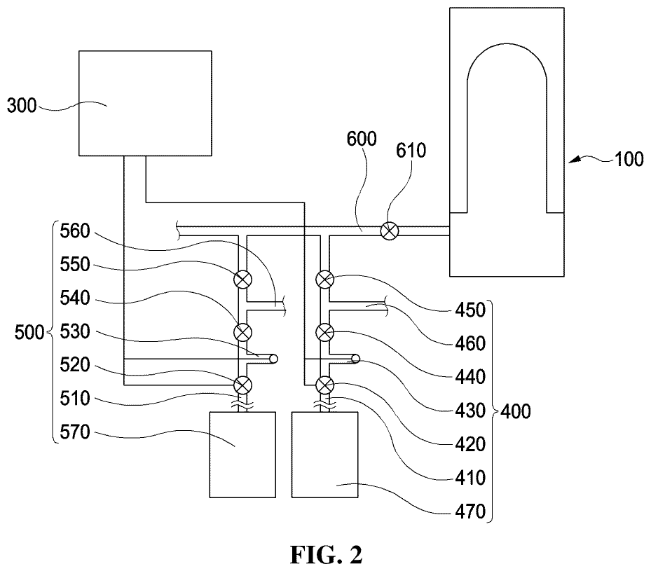

Hereinafter, one embodiment of the substrate processing equipment in accordance with the present invention will be described referring to FIG. 2.

After the supply of first process gas through the first gas supply unit (400) is completed, a cleaning process may be performed for the first gas supply unit (400), specifically the first supply line (410), by using purge and pumping.

Afterwards, before starting the supply of second process gas through the second gas supply unit (500), the pressure in the first supply line (410) at the rear end of the first control valve (420) may be measured using the first pressure sensor (430). If the measured pressure value is below the reference value, for example negative pressure, the supply of second process gas through the second gas supply unit (500) may then start.

Meanwhile, if the pressure value measured by the first pressure sensor (430) exceeds the reference value, for example positive pressure, then the supply of second process gas through the second gas supply unit (500) is not initiated and instead alarm occurs and the first control valve (420) may be blocked.

Afterwards, the second process gas supply through the second gas supply unit (500) may be performed, a cleaning process may be performed in the second gas supply unit (500), specifically in the second supply line (510), by using purge and pumping. Subsequently, the pressure at the rear end of the second control valve (520) of the second supply line (510) may be measured again using the second pressure sensor (530) to confirm whether the second process gas supply through the second supply line (510) has been blocked.

Meanwhile, during the supply of first process gas through the first gas supply unit (400), the pressure can be measured using the first pressure sensor (430) to confirm whether the normal supply is being made, and the pressure measurement from the second pressure sensor (530) can be used to monitor any leaks in the second supply line (510).

Similarly, during the supply of second process gas through the second gas supply unit (500), the pressure can be measured using the second pressure sensor (530) to confirm whether the normal supply is being made, and the pressure measurement from the first pressure sensor (430) can be used to monitor any leaks in the first supply line (410).

Hereinafter, the gas supply method in accordance with the present invention will be described with reference to the accompanying drawings.

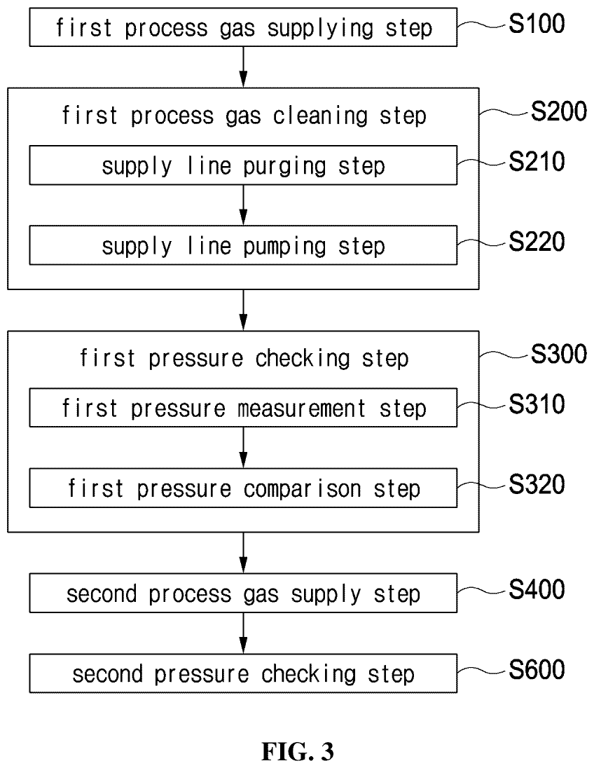

As shown in FIG. 3, the gas supply method in accordance with the present invention includes first process gas supplying step (S100) for supplying a first process gas to the processing space through a first gas supply unit (400) of the plurality of gas supplying units; first pressure checking step (S300) for checking whether the measured value of the first pressure sensor (430) of the first gas supply unit (400) is lower than or equal to preset reference value after the first process gas supplying step (S100); and second process gas supplying step (S400) for supplying second process gas different from the first process gas through a second gas supply unit (500) of the plurality of gas supplying units when the measured value is lower than or equal to the preset reference value.

In addition, the gas supply method in accordance with the present invention may further include first process gas cleaning step (S200) for performing cleaning of the first gas supply unit (400) after the first process gas supplying step (S100).

In addition, the gas supply method in accordance with the present invention may include supply valve blocking step (S500) for blocking the first supply valve (420) of the first gas supply unit (400), when measured value through the first pressure checking step (S300) exceeds the reference value.

In addition, the gas supply method in accordance with the present invention may further include second pressure checking step (S600) for checking whether measured value from the second pressure sensor (530) of the second gas supply unit (500) is below or equal to the preset reference value after the second gas supply step (S400).

The first gas supply step (S100) may be the step for supplying a first process gas to the processing space through a first gas supply unit (400) of the plurality of gas supplying units.

For example, the first process gas supply step (S100) is a step for supplying a first process gas to the processing space through a first gas supply unit (400) where the first process gas is supplied from the first process gas source (470) and may be supplied to the processing space through the first supply line (410) when the first control valve (420) is open.

At this time, the gas supply units other than the first process gas supply unit (400) have their control valves blocked, so that the process gas in the front end of the supply valve is maintained in charged state, and the rear end of the supply valve can be kept at or below a preset reference value, for example, negative pressure.

Meanwhile, in the first process gas supply step (S100) may be measured with the pressure using the first pressure sensor (430), and be confirmed whether the measured value is within a predetermined reference range of positive pressure, thereby monitoring whether the first process gas is being supplied normally.

Furthermore, in the first process gas supply step (S100) may be monitored whether the first process gas or other process gases are leaking in the supply line by measuring the pressure using the pressure sensors of the gas supply units other than the first gas supply unit (400) and confirming that the measured value is maintained at a negative pressure state.

The first process gas cleaning step (S200) may be a step that performs cleaning in the first gas supply unit (400) after the first process gas supply step (S100).

For example, the first process gas cleaning step (S200) may include supply line purging step (S210) for purging a first supply line (410) of the first gas supply unit (400), and supply line pumping step (S220) for performing pumping the first supply line (410) after the supply line purging step (S210).

The supply line purging step (S210) is a step that performs purging of the first supply line (410) of the first gas supply unit (400), and this can be done by supplying purge gas to the first supply line (410) through the aforementioned first purge gas supply line (460).

The supply line pumping step (S220) may remove the remaining first process gas and purge gas inside the first supply line (410) by pumping and draining the same after the supply line purging step (S210).

The first pressure checking step (S300) is a step that checks whether the measured value through the first pressure sensor (430) of the first gas supply unit (400) is below a preset reference value after the first process gas supply step (S100).

In other words, in the first pressure confirmation step (S300) may confirmed with the presence or absence of residual, leakage, and supply of the first process gas on the first supply line (510) by measuring the pressure through the first pressure sensor (430), and checking whether leakage and supply are blocked, thereby allowing the second process gas supply step (S400) to be performed.

For this, the first pressure checking step (S300) may include first pressure measurement step (S310) for measuring pressure of the supply flow path through the first pressure sensor (430), and first pressure comparison step (S320) for comparing the measured value from the first pressure measurement step (S310) with the reference value.

Here, the reference value is a preset absolute value, and for the different example, the reference value may be compared with an external pressure to confirm whether it is positive or negative pressure.

The first pressure checking step (S300) may not only check whether the measured value through the first pressure sensor (430) is below a preset reference value, but also simultaneously check whether the measured values obtained from the pressure sensors of the gas supply units other than the first gas supply unit (400) are below the reference value. If any other gas supply unit's measurement value exceeds the reference value, the second process gas supply step (S400) may not be performed and the supply valve blocking step (S500) may be performed instead.

Here, the first pressure checking step (S300) may further check whether the measured value obtained from the second pressure sensor (530) of the second gas supply unit (500) is below a preset reference value, differing from the example of checking whether the measured value obtained from the pressure sensor of the gas supply units other than the first gas supply unit (400) are below the reference value.

If the measured value through the first pressure sensor (430) is below the reference value, it can be determined that leakage and supply of the first process gas in the first supply line (410) have been blocked, allowing the second process gas supply step (S400) to be performed for the purpose of supplying the second process gas.

Here, the second process gas supply step (S400) may be a step for supplying first process gas and different second process gas to the processing space through the second gas supply unit (500), when the measured value is below the reference value in the first pressure checking step (S300).

The second process gas supply step (S400) may be a step for supplying the second process gas to the processing space through the second gas supply unit (500), which is one of the plurality of gas supply units.

For example, the second process gas supply step (S400) may be a step for supplying the second process gas through the second gas supply unit (500), where the second gas supply source (570) provides the second process gas to the second gas supply unit (500), and the second supply valve (520) is opened to supply the second process gas through the second supply line (510) to the processing space.

In this case, the other gas supply units except the second gas supply unit (500), have their supply valves blocked, so that the process gas is maintained in a charged state up to the front end of the blocked supply valve and maintains a negative pressure state, i.e., below a preset reference value, from the rear end of the blocked supply valve.

Meanwhile, the second process gas supply step (S400) is also capable of monitoring whether the second process gas is being supplied normally by measuring the pressure through the second pressure sensor (530) and confirming that the measured value is within a predetermined reference range of positive pressure.

Furthermore, the second process gas supply step (S400) can monitor whether the second process gas and other types of process gases are leaking from the supply lines by measuring the pressure through the pressure sensors of the gas supply units other than the second gas supply unit (500) and confirming that the measured values are maintaining a negative pressure state.

Meanwhile, when the measured pressure value obtained through the first pressure checking step (S300) exceeds the reference value, there is a risk of mixing between different process gases, and alarm can be generated. In this case, the supply valve blocking step (S500) can be performed.

The supply valve blocking step (S500) may be a step that blocks the first supply valve (420) of the first gas supply unit (400) when the measured value exceeds the reference value in the first pressure checking step (S300).

In other words, the supply valve blocking step (S500) may block the first supply valve (420) to prevent leakage of the first process gas at the rear end of the first supply valve (420), and even if the pressure measured by the first pressure sensor (430) exceeds the reference value in spite of this blocking, it can be assumed that there is a functional defect in the first supply valve (420) and therefore fundamentally block the supply of the first process gas from the first gas supply source (470).

Here, the supply valve blocking step (S500) not only blocks the first supply valve (420) of the first gas supply unit (400) but can also block the respective supply valves of the plurality of the gas supply units for safety reasons.

The second pressure checking step (S600) is a step that checks whether the measured value obtained through the second pressure sensor (530) of the second gas supply unit (500) is below the preset set reference value after the second process gas supply step (S400).

In other words, the second pressure checking step (S600) can be performed for the second gas supply unit (500), just like the first pressure checking step (S300) was performed for the first gas supply unit (400).

The first gas supply step (S100), the first pressure checking step (S300), the second gas supply step (S400) and the second pressure checking step (S600) may sequentially performed to form one single cycle and at least one single cycle, more preferably a plurality of single cycles may be performed, thereby enabling the alternative supply of the first process gas and the second process gas.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A substrate processing equipment comprising:
a process chamber (100) forming a processing space in which substrate processing is performed;
a plurality of gas supplying units (200), respectively comprising a supply line (210) formed with a supply flow path communicating with the processing space and delivering process gas from a process gas supply source (270), a supply valve (220) installed in the supply line (210) to open and close the supply flow path, and gas sensing means for sensing the process gas at a rear end of the supply valve (220) in the supply line (210); and
a control unit (300) for controlling supply of different process gases through the gas supplying units (200) based on the sensing result of the gas sensing means,
wherein prior to supplying process gas through at least one of the plurality of gas supplying units (200), the control unit (300) checks whether to block based on the sensing result of the gas sensing means of at least one of the remaining gas supplying units (200).

2. The substrate processing equipment of claim 1,
wherein the gas sensing means is a pressure sensor (230) that measures pressure of the supply flow path at the rear end of the supply valve (220), and
the control unit (300) checks whether to block supply of process gases before supplying process gases through any one of the gas supply units (200), based on pressure measurement value from the pressure sensor (230) of at least one of the remaining gas supply units (200).

3. The substrate processing equipment of claim 2,
wherein the control unit (300) starts to supply process gases through any one of the gas supply units (200), by comparing pressure measurement value from the pressure sensor (230) of at least one of the gas supply units (200) except at least one of the gas supply units (200) where process gas supply is scheduled, with a preset reference value, and when the measured pressure is lower than or equal to the reference value.

4. The substrate processing equipment of claim 3,
wherein the control unit (300) starts to supply process gases through any one of the gas supply units (200) which is scheduled for process gas supply, when the pressure measurement value of the pressure sensor (230) of at least one of the gas supply units (200) is lower than or equal to a predetermined threshold value.

5. The substrate processing equipment of claim 2,
wherein the control unit (300) starts to supply process gases through any one of the gas supply units (200), when the pressure measurement value from the pressure sensor (230) of at least one of the gas supply units (200) except any one of the gas supply units (200) where process gas supply is scheduled, is negative pressure.

6. The substrate processing equipment of claim 2,
wherein the control unit (300) blocks the supply valve (220) corresponding to the pressure sensor (230) that measures pressure exceeding preset reference value by comparing the pressure measurement value from the pressure sensor (230) of at least one of the remaining gas supply units (200) except the any one of the gas supply units (200), with the preset reference value, and when the pressure measurement value exceeds the reference value.

7. The substrate processing equipment of claim 2,
wherein the control unit (300) blocks supply of process gases from the above process gas supply source (270) by comparing the pressure measurement value from the pressure sensor (230) of at least one of the remaining gas supply units (200) except any one of the gas supply units (200), with the preset reference value, and when the pressure measurement value exceeds the reference value.

8. The substrate processing equipment of claim 2,
wherein the control unit (300) checks whether the process gas is being supplied normally by using the pressure measurement value from the pressure sensor (230) of at least one gas supply unit (200), during the supply of process gas through any one of the gas supply units (200).

9. The substrate processing equipment of claim 1, further comprising
a main supply line (600) the end of which is connected with the process chamber (100), and which is connected with the respective supply lines (210) of the plurality of gas supplying units (200).

10. The substrate processing equipment of claim 1,
wherein the plurality of gas supplying units (200) comprise
a first gas supply unit (400) comprising a first supply line (410) formed with a supply flow path for supplying first process gas, the supply flow path communicating with the processing space, a first supply valve (420) installed in the first supply line (410) to open and close the supply flow path, and a first pressure sensor (430) installed at the rear end of the first supply valve (420) in the first supply line (410) to measure the pressure of the supply flow path, and
a second gas supply unit (500) comprising a second supply line (510) formed with a supply flow path for supplying second process gas, the supply flow path communicating with the processing space, a second supply valve (520) installed in the second supply line (510) to open and close the supply flow path, and a second pressure sensor (530) installed at the rear end of the second supply valve (520) in the second supply line (510) to measure the pressure of the supply flow path.

11. The substrate processing equipment of claim 10,
wherein the first gas supply unit (400) further comprises a first control valve (440) which is installed at the rear end of the first supply valve (420) in the first supply line (410) to control flow rate of the first process gas, and
wherein the first pressure sensor (430) is installed at at least one of the front end and the rear end of the first control valve (440).

12. The substrate processing equipment of claim 10,
wherein the second gas supply unit (500) further comprises a second control valve (540) which is installed at the rear end of the second supply valve (520) in the second supply line (510) to control flow rate of the second process gas, and
wherein the second pressure sensor (530) is installed at at least one of the front end and the rear end of the second control valve (540).

13. A gas supply method trough a substrate processing equipment comprising: a process chamber (100) forming a processing space in which substrate processing is performed; a plurality of gas supplying units, respectively comprising a supply line formed with a supply flow path communicating with the processing space, a supply valve installed in the supply line to open and close the supply flow path and a pressure sensor for measuring pressure in the supply flow path at a rear end of the supply valve in the supply line, comprising
first process gas supplying step (S100) for supplying a first process gas to the processing space through a first gas supply unit (400) of the plurality of gas supplying units;
first pressure checking step (S300) for checking whether the measured value of the first pressure sensor (430) of the first gas supply unit (400) is lower than or equal to preset reference value after the first process gas supplying step (S100); and
second process gas supplying step (S400) for supplying second process gas different from the first process gas through a second gas supply unit (500) of the plurality of gas supplying units when the measured value is lower than or equal to the reference value.

14. The method of claim 13, further comprising
first process gas cleaning step (S200) for performing cleaning of the first gas supply unit (400) after the first process gas supplying step (S100).

15. The method of claim 14,
wherein the first process gas cleaning step (S200) comprises supply line purging step (S210) for purging a first supply line (410) of the first gas supply unit (400), and supply line pumping step (S220) for performing pumping the first supply line (410) after the supply line purging step (S210).

16. The method of claim 13,
wherein the first pressure checking step (S300) comprises first pressure measurement step (S310) for measuring pressure of the supply flow path through the first pressure sensor (430), and first pressure comparison step (S320) for comparing the measured value from the first pressure measurement step (S310) with the reference value.

17. The method of claim 13, comprising
supply valve blocking step (S500) for blocking the first supply valve (420) of the first gas supply unit (400), when measured value through the first pressure checking step (S300) exceeds the reference value.

18. The method of claim 17,
wherein the respective supply valves of the plurality of gas supply units are blocked in the supply valve blocking step (S500).

19. The method of claim 13,
the first pressure checking step (S300) further comprising step for checking whether measured value from the second pressure sensor (530) of the second gas supply unit (500) is below or equal to the preset reference value.

20. The method of claim 13, further comprising
second pressure checking step (S600) for checking whether measured value from the second pressure sensor (530) of the second gas supply unit (500) is below or equal to the preset reference value after the second gas supply step (S400),
wherein the first gas supply step (S100), the first pressure checking step (S300), the second gas supply step (S400) and the second pressure checking step (S600) are sequentially performed to form one single cycle and at least one single cycle is performed.
